(19) United States
(12) Patent Application Publication
(10) Pub. No.: US 2011/0126073 A1
(43) Pub. Date: May 26, 2011

(54) Error Correction in an Electronic Circuit

(76) Inventors: Andre K. Nieuwland, Waalre (NL); Paul Wielage, Waalre (NL); Richard P. Kleihorst, Kasterlee (BE)

(21) Appl. No.: 11/578,898

(22) PCT Filed: Apr. 26, 2005
(86) PCT No.: PCT/IB2005/051351

§ 371 Date: Nov. 21, 2007

(30) Foreign Application Priority Data
Apr. 29, 2004 (EP) 04101849.0

(51) Int. Cl. G06F 11/07; H03M 13/05; G06F 11/10

(52) U.S. Cl. 714/752; 714/799; 714/E11.024; 714/E11.032

(57) ABSTRACT

An electronic circuit has a data producing circuit (12), such as a matrix of memory cells. A capture circuit (14) has e an input coupled to the data producing circuit (10) for capturing the data signals after allowing a selected part of the data producing circuit to drive the input of the capture circuit. An error detection circuit (15) detects errors in the captured data signals. In response to detection of an error in particular data signals, the error detection circuit causes recapture of the particular data signals, allowing the data producing circuit (10) to drive the data signals at the input of the capture circuit (14) during a second time interval until recapture, the second time interval having a longer duration than the first time interval. This makes it possible to select the duration of the first time interval allowing for average driving speed of circuit parts (e.g. memory cells), without using a duration designed to account for worst case driving speed that may occur due to spread. Errors caused by spread are corrected by rereading with an increased time interval for driving the input of the capture circuit. Preferably, the duration of the first time interval is regulated so that on average a predetermined error rate occurs.

The invention relates to a digital electronic circuit and in particular to an electronic circuit that comprises one or more memory matrices.

Prevention of errors is becoming an increasingly important design aspect of integrated circuits. U.S. Pat. No. 6,360,346, for example, discloses how an error correcting code (ECC) can be used to correct errors during memory read operations. This type of correction makes use of the fact that most bits will typically be read correctly from a memory, only a fraction of the bits producing errors. If there are too many errors memory blocks, or even the whole circuit is discarded.

There are many potential sources of errors in integrated circuits. In the past the large number of memory cells in a memory, and the need to reduce the size of cells to the limit of what is technologically possible have made it difficult to produce error free memories with high yield. With the progressive reduction of semi-conductor feature size statistical spread in the number of implanted atoms in different transistors is becoming a new source of errors. Typically this type of error does not lead to completely defective memory cells, but rather it makes it impossible to find a single threshold that suits all cells. US patent application No. 2002/0122344 discloses a circuit which reduces the effect of this spread. Nevertheless errors are difficult to prevent and it has been found to be more efficient to accept a number of defective cells, using correction techniques to correct errors.

Speed is another important performance requirement of electronic circuits. The higher the speed the more computations can be executed per second, making the electronic circuit more valuable. The maximum possible speed of electronic circuits is limited by the time needed to allow signals to develop in the circuit. Digital signals are represented by analog signals such as voltages and or currents that can only change at a finite rate, making it necessary to leave some time for the signals to develop before the represented digital values can be captured.

A memory provides an illustration of this requirement. A memory matrix typically contains word lines for addressing the cells and bit lines and rows and columns of memory cells. Each word line corresponds to a row and the cells in each row are coupled to a respective bit line. Each bit line corresponds to a column, cells in each column being coupled in common to a respective bit line. Capture circuits, which typically include a sense amplifier, are coupled to the bit lines. When a cell is accessed, a signal on the word line of its row makes the cell influence a signal on the bit line of its column. After a delay that allows this influence to develop into a detectable signal, the capture circuit is triggered to latch into a state determined by the signal. Since many cells are coupled to the same bit line the influence of the cell on the signal on the bit line is relatively weak, which makes it necessary to use a relatively long delay. This limits the speed of the memory circuit.

The need to give signals sufficient time to develop before they can be captured sets a ceiling on the maximum possible speed. If the signal is captured to soon unpredictable outputs result not just for individual bits, but for entire words, which makes it impossible to use error correction techniques. Accordingly, much work has been invested in minimizing the required time, for example by using smaller circuit dimensions, which reduces capacitances that counteract signal development, by reducing the required signal swing or by using stronger drive circuits.

Nevertheless it is unavoidable that the speed must be limited. Conventionally this is done by setting the clock speed of the integrated circuit, or at least of the memory, to a value that allows sufficient signal development before the start of capture. It is also known to set the speed adaptively, in response to the output signal development caused by a reference cell with known content. In the prior art this kind of technique is used as a time reference for a memory as a whole, or at least for groups of memory cells to ensure sufficient time for signal development. In this case the memory is self-timed.

In this way a worst-case scenario determines the speed. If there is a statistical spread in the speed of different memory cells, some cells will develop signals more slowly than others, but it is impossible to predict which cells. Therefore, the reference cell approach will predict less accurately the timing of the other memory cells. To avoid an overdose of errors the speed must be set a number of standard deviations of the speed below the speed that is acceptable for average cells. The larger the memory, the lower the speed must be set.

Among others, it is an object of the invention to provide for an electronic circuit that is capable of performing with a low error rate with an average speed that is higher than the speed dictated by worst-case design for that error rate.

Among others, it is an object of the invention to reduce the effect of statistical spread in the number of implanted ions on the maximum average operating speed of an integrated circuit.

A circuit according to one aspect of the invention is set forth in Claim 1. The circuit produces data signals and captures the data signals, capture starting after a first time interval during which the data producing circuit (such as addressed memory cells) are allowed to drive the input of the capture circuit (capture, as used herein, means causing the digital output of the capture circuit to become fixed so that it is no longer influenced by subsequent development of its input signals). According to the invention production and capture is retried with a longer second time interval when an error is detected, or at least when an uncorrectable error is detected. In a memory, in particular, an addressed cell is may be addressed again when an (uncorrectable) error is detected, and data from the cell is captured the second time interval after addressing, or the capture circuit is reset and allowed to be driven during the second time interval after release from reset.

Recapture of data with extended duration represents a loss of throughput speed, but it makes it possible to use a shorter duration for first capture, because errors due to excessive speed at first reading can be tolerated. As a result the average throughput rate, the number of correct data signals that can be produced per second, is higher than can be achieved by setting the first time interval to allow for worst case conditions. This is particularly advantageous for circuits with large numbers of sub-circuits, such as memory cells, that have a statistical spread in the maximum possible capture speed. In this case the higher average speed is effectively used to compensate excessively low speed of some sub-circuits.

In an embodiment the duration of the first time interval, used to capture data signals first when no error has yet been detected in the data signal, is regulated so that a set error rate occurs. Thus, the speed of the circuit can be optimized. In a further embodiment the duration is regulated to a set (non zero) rate of uncorrectable errors and/or recapture with extended duration is used in response to detection of uncorrectable errors. This can even be used by itself, without recapture with extended duration, for example if a certain amount of errors can be tolerated. In a circuit with a plurality of memories that can be used in parallel, the distribution of data over the memories can be adapted to the different average speeds that can be realized by the different memories. A larger fraction of the data may be stored in memories with a higher speed and a smaller fraction of the data may be stored in memories with a lower speed. In this way the average speed can be optimized.

Recaptured data takes the place of the originally erroneous data during further processing of the data, at least if no error correction was possible. This may be realized for example by recapturing the data with extended duration between capture of data for subsequent addresses with normal duration, and insertion of the recaptured data at its original position for further processing, out of order with the data for the subsequent addresses. As an alternative, block based reading may be used, data from a block that contained errors being recaptured after reading of the block has been completed.

These and other objects and advantage of the invention will be described in more detail using the following figures.

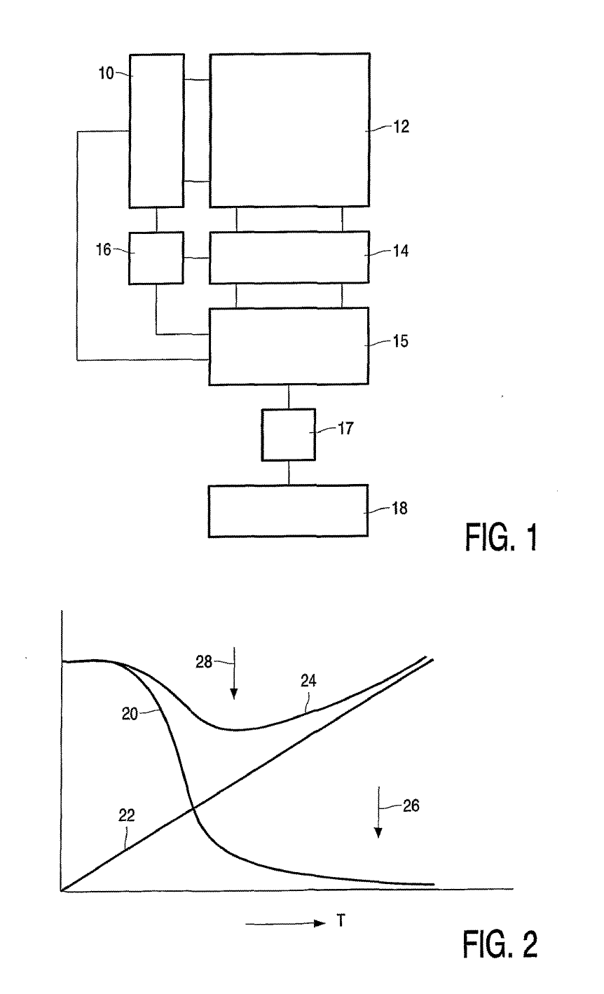

FIG. 1 shows an electronic circuit

FIG. 2 illustrates a trade-off between read delay and average throughput

FIG. 1 shows an electronic circuit, comprising a data producing circuit in the form of a memory matrix 12, an addressing circuit 10, a sensing circuit 14, an error correction and detection circuit 15, a timing circuit 16, a buffer memory 17 and a processing circuit 18. Addressing circuit 10 has an addressing output coupled to memory matrix 12. Memory matrix 12 has bit line outputs coupled to sensing circuit 14. Sensing circuit 14 has digital outputs coupled to error correction and detection circuit 15. Error correction and detection circuit 15 has a first control output coupled to timing circuit 16, a second control output coupled to addressing circuit 10 and a data output coupled to buffer memory 17. Timing circuit 16 has timing control outputs coupled to addressing circuit 10 and sensing circuit 14. Buffer memory 17 has an output coupled to processing circuit 18.

In operation addressing circuit 10 successively addresses words corresponding to groups of memory cells in memory matrix 12. When addressed, the cells from a group are coupled to the bit lines so that they influence the signal levels on the bit lines. Sensing circuit 14 captures data from the bit lines, converting the signals on the bit lines into digital values. Error correction and detection circuit 15 receives the digital values and detects and corrects errors in these digital values. For this purpose error correction and detection circuit 15 typically makes use of an Error Correcting Code (ECC), which defines a set of multi-bit codewords selected so that the codewords mutually differ at least at a predetermined number of bits. Data stored in each group of cells memory matrix 12 represents a word selected from the set of codewords, so that in the absence of errors the digital value output to error correction and detection circuit 15 corresponds to the selected codeword from the set of codewords. But due to errors the digital value may differ from the selected codeword. Error correction and detection circuit 15 detects this, and determines which codeword differs least from the digital value. This codeword corresponds to a decoded data value, which error correction and detection circuit 15 writes to buffer memory 17. Processing circuit 18 reads and processes the decoded data values from buffer memory 17.

Although addressing circuit 10 is shown as a separate circuit for the sake of clarity, it should be understood that in practice the addresses may be selected by processing circuit 18, making processing circuit 18 in a sense part of addressing circuit 10.

Timing circuit 16 controls timing of reading. Timing circuit 16 provides start signals to addressing circuit 10, which control the timing of addressing of groups of memory cells in memory matrix 12. Timing circuit 16 also provides capture signals to sensing circuit 14. The capture signals control when signals from the bit lines will be used to capture data. The way in which the capture signals are applied depends on the type of sense amplifier. For example, one type of sense amplifier (such as used in DRAMs for example) contains a pair of cross-coupled inverters which are enabled by the capture signal, one inverter having an input coupled to the bit line, the other having an input coupled to a reference line (not shown). When enabled, such a sense amplifier drives itself to one of two stable states, dependent on the initial signal on the bit line. In this case the capture triggers enabling of the inverters. Another type of sensing circuit contains a latch with an input coupled to a bit line (typically via an amplifier or a comparator). In this case the latch is clocked in response to the capture signal. Other types of sensing circuits that use capture timing signals are also possible. In each case the sensing circuit captures a digital value determined by a signal or signals on the bit lines at a time determined by the capture signal.

One additional advantage of the proposed method is that power is saved since the bit-lines are driven for a shorter time on average. Therefore, the voltage swing is lower, resulting in less power dissipation. The sense-amplifiers and meta-stable latches also consume power. When controlling the timing, the sense amplifier and latches are preferably enabled with a delay, to avoid keeping them in a meta-stable state for a longer period of time.

The duration of the delay between the start signal and the capture signal at least partly determines the cycle frequency of the memory. Timing circuit 16 typically applies a new start signal to addressing circuit 10 with a predetermined time interval after generating the capture signal for capturing the previous data value. Hence, the longer the duration of the delay between the start signal and the capture signal, the longer the cycle time between successive start signals.

Timing circuit 16 sets the duration of the delay between the start signal and the capture signal so that in a majority of cases the signals on the bit lines get sufficient time to develop to a level that enables capture occurs with sufficient accuracy that no errors, or at least with so few errors that error correction is possible. However, the delay is not set to a duration so that all cells get sufficient time to develop signals that are sufficiently large to enable reliable detection. Statistical spread in the number of implanted atoms in transistors of the cells may have the effect that the drive strength of some of the cells is too weak to allow capture with sufficient reliability after the delay determined by timing circuit 16.

In a first embodiment error correction and detection circuit 15 signals detection of an uncorrectable error in a particular data value to addressing circuit 10 and timing circuit 16. In response, addressing circuit 10 readdresses the group of memory cells that gave rise to this particular data value. Timing circuit 16 controls the delay between the start of readdressing of this group of cells and capture by sensing circuit 14. Timing circuit 16 sets this delay for rereading to a higher value than used for addressing and sensing of signal values cells during first reading. Error correction and detection circuit 15 receives the data value read with the increased delay and writes it into buffer memory 17 at, the place of the data value for the original read operation. As an alternative, if the address of the erroneous data value still controls the selected group of memory cells, readdressing may be omitted and rereading may proceed immediately, after resetting sensing circuit with increased delay after resetting. (In a known sensing circuit for example, resetting includes decoupling the connection between the bit lines and the sensing circuit and equalizing the input signals, of the sensing circuit. After reset, equalizing is discontinued and the bit lines are coupled-to the input of the sensing circuit again, to start a new sensing operation).

Optionally, the data value read with the extended delay is also used to write back to the memory cells from which it was read. If the error was caused by overly short timing this provides no additional advantage, but if other sources of error exist, which cannot be distinguished from timing errors, write back may reduce the probability of recurrence of these errors.

Typically processing circuit 18 processes data values in packets of multiple words. Processing circuit 18 starts processing of a packet is started once all data for the packet has been read successfully in this way. Alternatively, buffer memory 17 may be a breathing buffer, like a FIFO buffer that absorbs variations in delay before valid data is available. In this case it may be necessary to pause reading from memory matrix if a low error rate occurs, when the FIFO buffer signals that it is full. In another embodiment processing circuit performs a function like image decoding wherein frames need to be produced before predetermined time points, but variations in the delay before delivery of data are permissible before these time points. In this case that task performed by processing circuit 18 may be designed so that it nominally leaves some spare time before the time points, if no read errors occur, processing circuit 18 remaining in step with reading (i.e. pausing if a reread is required).

It should be appreciated this embodiment relies on a trade-off: decreasing the delay between the start signal and the capture signal increases the number of memory cycles that can be performed per second. But if the delay is decreased this increases the number of additional (longer) cycles that is needed to read corrected data, thereby reducing the number of data values that can be read per second.

FIG. 2 illustrates this trade-off. Three curves are shown as a function of the normal cycle-time T used for reading from memory matrix 12. A first curve 20 shows the number of cycles needed for rereading due to errors. As can be understood, for a high cycle time T little or no errors occur, because even the weakest memory cells get sufficient time to develop signals that are large enough to be captured reliably. As a result the number of cycles for rereading is small. As the cycle time decreases an increasing number of memory cells has insufficient drive strength, until for zero cycle time all memory cells have insufficient drive strength. As a result the number of cycles for rereading increases with decreasing cycle time T.

A second curve 22 (a straight line) shows the normal cycle time needed to read data if no error occurs. A third curve 24 shows the average cycle time obtained by the longer cycle time for rereading, multiplied by the fraction of memory cells that requires rereading, added to the normal cycle time. As can be seen, an optimum cycle time occurs (indicated by arrow 28). This optimal cycle time should be contrasted with a “safe” worst case cycle time (indicated by arrow 26) selected to avoid an excessive number of errors. As can be appreciated, by using rereading the average cycle time, and thereby the throughput time of packets time can be reduced.

Various possibilities exist for selecting the higher delay during rereading. For example, a predetermined worst-case higher delay may be used during rereading, which will ensure correct reading with a required minimum probability. As another example, a first higher delay duration may be used first and if this again results in an error the data may be reread again, using a second, even higher delay. The second delay may be a predetermined worst case delay or it may be followed by rereading at a third even higher delay and so on.

In a further embodiment error correction and detection circuit 15 triggers rereading immediately when an error is detected. If the circuit is sufficiently fast to detect the error before the start of the next read operation this may be used to ensure that no next address is read before the preceding address has been read successfully. However, in another embodiment rereading may be done out of order, inserting a reread of a word after a predetermined number of successive addresses has been read subsequently to first reading of the word. In yet another embodiment rereading may be performed after a predetermined block of addresses has been read. In this embodiment addressing circuit 10 for example records the addresses for which rereading is required, sets timing circuit 16 to the higher delay after completion of reading from the block, and next addresses memory matrix 12 at the addresses for which a need to reread has been recorded.

In a second embodiment timing circuit 16 uses the error rate of errors signalled by error correction and detection circuit 15 to regulate the delay between the start signal and the capture signal. If the average error rate is below a set level timing circuit 16 reduces the delay. If the average error rate is above a set level timing circuit 16 increases the delay. Various methods of selecting the set level are possible, generally designed to select the set level so that maximum throughput is realized with no more than an acceptable number of errors. In one embodiment a maximum tolerable error rate R is specified dependent on the function of the apparatus (in a television set, for example, this rate follows from a rate at which frame errors may occur). Given information about the ECC that is used it is determined which bit error rate B in the uncorrected words leads to errors that cannot be corrected with the ECC at an uncorrectable error rate R corresponding to the maximum tolerable error rate (typically if n−1 errors can be corrected R=Bⁿ). Next the speed is regulated so that the observed average bit error rate assumes a value slightly below the computed bit error rated B.

Any type of regulation may be used. The rate of errors may be averaged for example and a difference between the average and the set value may be used to adjust the delay. As an alternative, the delay may be increased by a first step for each word wherein an error is detected and decreased by a second step for each word wherein no error is detected, the ratio between the first and second step being selected dependent on the set level. In a further embodiment the step size may be adapted dependent on a detected number of errors in a word.

This second embodiment may be combined with the first embodiment to select the delay between the start signal and the capture signal for first reading, so as to optimize the average compound throughput speed (curve 24 in FIG. 2). The set value of the error rate may be selected from an analysis of the statistical spread for example. Otherwise timing circuit may be arranged to measure the throughput for different values of the delay and to set the delay at the value that realizes the highest average throughput.

However, the second embodiment can also be used separately from the first embodiment, for example if the performance specification of the circuit permits a certain average error rate (e.g. as noise during audio or video signal decoding). In another embodiment the data from memory may contain additional error correction information that permits processing circuit 18 to correct errors up to a certain average rate. In this case the speed may be regulated so that this error rate is realized.

Although a particular embodiment of the invention has been disclosed, it will be appreciated that the invention is not limited to this embodiment. For example, although an application to reading from a memory matrix 12 has been shown, the invention may be applied to other circuits as well. For example, the invention may be applied to errors caused by capturing data at the output of a logic circuit too quickly. In this case errors at the output of the logic circuit may be detected by using circuits to generate redundant signal, or by performing some consistency check on the output signal. In one embodiment, the delay between the application of input data to the logic circuit and capture of results is adapted in a control loop so that the error rate is regulated to a set level. In another embodiment, the circuit responds to detection of an error by applying the same input data anew at the input of the logic circuit and repeating capture, this time with a larger delay. In this way, a high average throughput can be realized, while correcting errors if slow parts of the logic circuits are involved. Reapplication of the same input data can be realized for example by restarting a sub-task executed by the circuit, e.g. by processing the same data for a second time. Of course both these embodiment may be used in combination.

As another example of alternative applications of the invention, a plurality of memory matrices may be provided in parallel, so that data can be reread from any individual memory matrix independently of rereading from the other memory matrices. A common processing circuit is provided that processes combined data from the parallel memories. In this embodiment the circuit may be arranged to control the distribution of the combined data over the memories dependent on the throughput rate that can be realized with each memory. Preferably the data is distributed so that the fastest memories are filled completely and the slowest memories are left empty, or used for processing tasks that do not require a high throughput speed. As an alternative respective fractions of the combined data are stored in respective memories, the fraction stored in a memory being proportional the average throughput rate of the memory divided by the sum of the average throughput rates of all memories (the average throughput rate being the average number of words that can be produced from the memory per second).

Furthermore it should be realized that in some embodiments the words stored in memory matrix 12 need not be words from an ECC. For example, the information to detect and/or correct errors in the words may be supplied from another source than memory matrix 12. Nor is it necessary that error detection and correction should be performed a word at a time. For example, errors may be detected and corrected in a block of words that have been read successively from memory matrix 12. In this case rereading of erroneous words may be delayed until the whole block has been read and analysed for errors. Similarly, regulation of the delay between start signals and capture signals may be performed on a block basis.

Furthermore it should be appreciated that error detection and correction circuit 15 may be realized as a dedicated circuit, but that its function may also be performed by processing circuit 18. In both cases dedicated error correction hardware and/or suitably programmed programmable hardware could be used. If processing circuit 18 performs error detection, it may request rereading with a longer delay at any time and at its own discretion, omitting a reread if no corrected data is needed for processing purposes, for example.

In a further embodiment, when an error that can be corrected only by reading with increased delay is detected for a group of memory cells, it is recorded in an auxiliary memory that for that group of cells an increased delay is needed. In this case, during a next reading of the group of cells, the auxiliary memory is consulted and if it is recorded there that an increased delay is needed, the increased delay is used immediately, without first attempting to read with the shorter delay. The information from the auxiliary memory may also be used for increasing the delay for the same selected groups of cells during writing. This reduces write errors, since delay related errors for specific groups of cells typically occur both for reading and writing.

1. An electronic circuit comprising
a data producing circuit having an output for producing data signals;
a capture circuit having an input coupled to the output of the data producing circuit for capturing the data signals;
a timing circuit for controlling a duration of a first time interval during which the data producing circuit is allowed to drive the data signals at the input of the capture circuit until capture;
an error detection circuit having an input coupled to the capture circuit, for detecting errors in the captured data signals, the error detection circuit being coupled to the timing circuit for, in response to detection of an error in particular data signals, causing recapture of the particular data signals, allowing the data producing circuit to drive the data signals at the input of the capture circuit during a second time interval until recapture, the second time interval having a longer duration than the first time interval.

2. An electronic circuit according to claim 1, wherein the data producing circuit comprises a memory matrix and an addressing circuit that generates addressing signals for selecting memory cells in the memory matrix the data signals being driven from the addressed memory cells, dependent on the content of the addressed memory cells.

3. An electronic circuit according to claim 2, wherein said first and second time interval last from application of the addressing signals to the memory matrix until subsequent capture and recapture respectively.

4. An electronic circuit according to claim 1, wherein said first and second time interval last from release of the capture circuit from a reset state until subsequent capture and recapture respectively.

5. An electronic circuit according to claim 1, wherein the timing circuit is arranged to regulate, under control of an average rate of detected errors, the duration of the first-time interval for capturing data signals subsequent to the errors.

6. An electronic circuit according to claim 1, wherein the data signals represent codewords from an Error Correcting Code, the error detection circuit being arranged to correct errors according to the Error Correcting Code, the error detection circuit causing recapture in response to detection of an error that does not meet a criterion for correctability for the Error Correcting Code, but not in response to errors that meet said criterion.

7. An electronic circuit according to claim 2, wherein the addressing circuit is arranged to read data for a block of successive addresses, to store information that identifies one or more reread addresses for which the error detection circuit has detected errors during reading from addresses of the block, and to reread data from addressed determined by the stored reread addresses with the second time interval after completion of a first cycle of reading from addresses from the block.

8. An electronic circuit according to claim 2, wherein the addressing circuit is arranged to generate addressing signals for a first address followed in a temporal sequence by further addresses for reading using said first time interval, and to insert, in response to detection of an error in the data signal for the first address, the first address among the further addresses at a predetermined number of positions after the first address in the temporal circuit, for rereading from the first address using the second time interval.

9. An electronic circuit according to claim 1, wherein the error detection circuit is coupled to the addressing circuit, which is arranged to extend a duration during which an addressing signal is applied to the memory matrix in response to detection of an error in the data signals read using that addressing signal, the timing circuit causing the capture circuit to return to a reset state and allowing the addressed memory cells to drive data signals at the input of the capture circuit during second time interval from release the reset state until subsequent recapture.

10. An electronic circuit according to claim 1, wherein the first time interval has a value that substantially minimizes a sum as a function of the duration of the first time interval, wherein the sum is a sum of said duration and the duration of the second time interval weighted by a fraction of data signals that contain said errors when said first time interval is used for first capture.

11. An electronic circuit according to claim 1, comprising a processing circuit and a buffer memory coupled between the capture circuit and the processing circuit for transfer of information derived from the data signals, the buffer memory being arranged to absorb timing variations due to rereading of data signals.

12. A method of processing data, the method comprising
applying successive control signals to a data producing circuit;
producing successive data signals with a selected part of the data producing circuit, that are selected under control of the control signals;
allowing the selected part to drive an input of a capturing circuit with the data signals;
capturing the data signals after driving during a first time interval;
detecting whether an error has occurred in the captured data driven by a particular selected part of the data producing circuit;
recapturing the data signals after allowing the particular selected part of the data producing circuit drive the input of the capture circuit during a second time interval, which has a longer duration than the first time interval, in response to detection of the error.

13. A method according to claim 12, wherein the duration of the first time interval is selected so that it substantially minimizes a sum as a function of the duration of the first time interval, wherein the sum is a sum of the duration of the first time interval and the duration of the second time interval weighted by a fraction of data signals that contain said errors when said duration delay of the first time interval is used for first capture.

14. A method according to claim 12, wherein data is read from a memory matrix the selected parts of the data producing circuit being addressed cells in the memory matrix the addressed cells driving the input of the capture circuit.

15. A method according to claim 12, comprising the step of regulating the duration of the first time interval dependent on a detected error rate.

16. An electronic circuit comprising
a data producing circuit, having an output for producing data signals from selectable parts of the data producing circuit;
a capture circuit having an input coupled to the output of the data producing circuit for capturing the data signals;
a timing circuit for controlling a duration of a time interval during which the selected parts are allowed to drive the input of the capture circuit until capture;
an error detection circuit having an input coupled to the capture circuit, for detecting errors in the captured data signals, the error detection circuit being coupled to the timing circuit, for regulating the duration of the time interval for capturing data signals subsequent to the errors, so that an average error rate is regulated to a set value greater than zero.

17. A method of processing data the method comprising
generating successive control signals;
producing data signals from circuits selected in response to respective ones of the control signals;
capturing the data signals, after allowing the selected circuit to drive an input of a capture circuit during a time interval;
detecting errors in the captured data signals;
regulating the duration of the time interval subsequent to the errors, so that an average error rate is regulated to a set value greater than zero.
